(19) United States
(12) Patent Application Publication
(10) Pub. No.: US 2008/0117344 A1
(43) Pub. Date: May 22, 2008

(54) LIQUID CRYSTAL DISPLAY PANEL, METHOD FOR FABRICATING THE SAME, AND THIN FILM TRANSISTOR SUBSTRATE

(75) Inventors: Beom Jun KIM, Seoul (KR); Sang Youn HAN, Cheonan-si (KR); Byeong Jae AHN, Suwon-si (KR); Sang Yong NO, Seoul (KR); Shin Tack KANG, Yongin -si (KR); Hyeong Jun PARK, Cheonan-si (KR)

Correspondence Address: H.C. PARK & ASSOCIATES, PLC, 8500 LEESBURG PIKE, SUITE 7500, VIENNA, VA, 22182, US

(73) Assignee: SAMSUNG ELECTRONICS CO., LTD., Suwon-si (KR)

(21) Appl. No.: 11/838,385

(22) Filed: Aug. 14, 2007

(30) Foreign Application Priority Data
Nov. 17, 2006 (KR) 10-2006-0113749

(51) Int. Cl. G02F 1/1343; H01L 21/84; H01L 29/06

(52) U.S. Cl. 349/39; 257/59; 438/155; 257/E29.003; 257/E21.7

(57) ABSTRACT

A liquid crystal display panel includes a first substrate, a second substrate facing the first substrate, and a liquid crystal layer interposed therebetween. The second substrate includes gate lines, data lines crossing the gate lines to define sub-pixel regions, a thin film transistor connected to a gate line and a data line, an organic passivation layer, a pixel electrode connected to the thin film transistor, a repair portion where the pixel electrode overlaps with a previous gate line, and a repair hole formed in the repair portion to penetrate the organic passivation layer. The pixel electrode is arranged in the repair hole. A method for repairing a defective pixel includes connecting a gate extending portion of the previous gate line to the pixel electrode in the repair portion using a laser, and cutting the defective pixel's drain electrode connected to the pixel electrode.

### CROSS-REFERENCE TO RELATED APPLICATION

This application claims priority from and the benefit of Korean Patent Application No. 10-2006-0113749, filed on Nov. 17, 2006, which is hereby incorporated by reference for all purposes as if fully set forth herein.

### BACKGROUND OF THE INVENTION

1. Field of Invention

The present invention relates to a liquid crystal display (“LCD”) panel and, more particularly, to an LCD panel in which a repair defect may be prevented when a defective pixel of an LCD panel is repaired, and a method for fabricating the same.

2. Discussion of the Background

An LCD device includes an LCD panel for displaying an image, a panel driver for driving the LCD panel, and a backlight unit for supplying light to the LCD panel.

The LCD panel includes a thin film transistor (“TFT”) substrate, a color filter substrate, and a liquid crystal layer interposed between the TFT substrate and the color filter substrate. The TFT substrate has a TFT array formed thereon, and the color filter substrate has a color filter array formed thereon.

The TFT substrate includes gate lines arranged in a first direction, data lines arranged in a direction substantially perpendicular to and crossing with the gate lines to define a matrix of sub-pixel regions, TFTs arranged at crossing points of the gate lines and the data lines, and a pixel electrode connected to each TFT. In order to increase an aperture ratio of the LCD panel, an organic passivation layer may be arranged on the TFT substrate, and the pixel electrode is arranged to partially overlap with the gate lines and the data lines.

The color filter substrate includes a black matrix for preventing light from being leaked, a color filter arranged in each sub-pixel region corresponding to a pixel electrode to realize a color, and a common electrode for generating an electric field between the common electrode and the pixel electrode.

The panel driver includes a gate driver for driving the gate lines of the TFT substrate and a data driver for driving the data lines. The gate driver supplies a scan signal to a gate line to turn on the TFT connected to the gate line, and the data driver supplies a data signal to the TFT that is turned on by the scan signal to charge a pixel data signal in the pixel electrode.

If a sub-pixel has a defect, a repair process may be performed on the LCD panel. To perform the repair process, the pixel electrode of the defective sub-pixel is short-circuited to be connected to the previous gate line by a laser beam. Then a signal of the previous gate line having an off voltage is supplied to the pixel electrode of the defective sub-pixel so that the defective sub-pixel is turned off and displays black even when a data signal is provided to the defective sub-pixel TFT. Since the organic passivation layer may have a thickness of more than several micro meters (μm), a laser short circuit defect may occur between the pixel electrode and the previous gate line. Specifically, since the organic passivation layer may be thick, the pixel electrode and the previous gate line may not be sufficiently connected to each other or short-circuited by a laser beam. Alternatively, even if the pixel electrode and the previous gate line are connected to each other, the connection area may be small. If the connection area is sufficiently small, the pixel electrode and the previous gate line may be disconnected later.

### SUMMARY OF THE INVENTION

This invention provides an LCD panel in which the pixel electrode is arranged to overlap with a previous gate line portion. Thus, the pixel electrode and the previous gate line may be connected during a repair process, and a connection defect may be prevented between the pixel electrode and the previous gate line after the repair process.

This invention also provides a method for fabricating the LCD panel.

This invention also provides a TFT substrate in which the pixel electrode is arranged to overlap with a previous gate line portion in a repair portion.

Additional features of the invention will be set forth in the description which follows, and in part will be apparent from the description, or may be learned by practice of the invention.

The present invention discloses an LCD panel including a first substrate, a second substrate facing the first substrate, and a liquid crystal layer interposed between the first substrate and the second substrate. Further, the second substrate comprises a gate line arranged on the second substrate, a data line crossing with the gate line, a gate insulating layer being interposed between the gate line and the data line, a thin film transistor connected to the gate line and the data line at a crossing point of the gate line and the data line, an organic passivation layer arranged on the TFT, a pixel electrode arranged in the sub-pixel region and connected to the TFT via a pixel contact hole penetrating the organic passivation layer, a repair portion comprising a region where the pixel electrode overlaps with a previous gate line, and a repair hole arranged in the repair portion to penetrate the organic passivation layer.

The present invention also discloses a method for fabricating a liquid crystal display panel including preparing a first substrate including a black matrix defining a sub-pixel region, preparing a second substrate to face the first substrate, and interposing a liquid crystal layer between the first substrate and the second substrate. Further, preparing the second substrate includes forming a gate line on the second substrate, forming a gate insulating layer on the gate line, forming a data line to cross with the gate line, the gate insulating layer being interposed between the gate line and the data line, forming a TFT connected to the gate line and the data line at a crossing point of the gate line and the data line, forming an organic passivation layer on the TFT, the organic passivation layer including a pixel contact hole exposing a portion of a drain electrode of the TFT, forming a pixel electrode on the sub-pixel region and connecting the pixel electrode to the TFT via the pixel contact hole, forming a repair portion where the pixel electrode overlaps with a previous gate line, and forming a repair hole in the repair portion to penetrate the organic passivation layer.

The present invention also discloses a thin film transistor substrate including a substrate, a gate line arranged on the substrate, a data line crossing with the gate line, a gate insulating layer being interposed between the gate line and the data line, a thin film transistor connected to the gate line and the data line at a crossing point of the gate line and the data line, an organic passivation layer arranged on the thin film transistor, a pixel electrode arranged on the substrate in a sub-pixel region and connected to the thin film transistor via a pixel contact hole penetrating the organic passivation layer, and a repair portion arranged where the pixel electrode overlaps with a previous gate line.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a plan view illustrating a TFT substrate of an LCD panel according to an exemplary embodiment of the present invention.

FIG. 2 is a cross-sectional view taken along line I-I′ and line II-II′ of FIG. 1.

FIG. 3 is a cross-sectional view taken along line II-II′ of FIG. 1, illustrating a repair portion in which a corresponding portion of an inorganic passivation layer is removed.

FIG. 4 is a plan view illustrating the TFT substrate of FIG. 1 after a repair process according to the exemplary embodiment of the present invention.

FIG. 5 is a cross-sectional view taken along line III-III′ of FIG. 4.

FIG. 6 is a cross-sectional view illustrating an LCD panel with the TFT substrate of FIG. 1 according to an exemplary embodiment of the present invention.

FIG. 7A, FIG. 7B, FIG. 7C, FIG. 7D, and FIG. 7E are cross-sectional views illustrating a process of fabricating the TFT substrate of FIG. 1.

FIG. 8 is a plan view illustrating a color filter on TFT array (“COA”) substrate of an LCD panel according to another exemplary embodiment of the present invention.

FIG. 9 is a cross-sectional view taken along line V-V′ and line VI-VI′ of FIG. 8.

FIG. 10 is a cross-sectional view taken along line VI-VI′ of FIG. 8, illustrating a repair portion in which a corresponding portion of an inorganic passivation layer is removed.

FIG. 11 is a cross-sectional view illustrating an LCD panel with the COA substrate of FIG. 8 according to another exemplary embodiment of the present invention.

FIG. 12A, FIG. 12B, FIG. 12C, FIG. 12D, FIG. 12E, and FIG. 12F are cross-sectional views illustrating a process of fabricating the COA substrate of FIG. 8.

### DETAILED DESCRIPTION OF THE ILLUSTRATED EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. In the drawings, the size and relative sizes of layers and regions may be exaggerated for clarity. Like reference numerals in the drawings denote like elements.

It will be understood that when an element such as a layer, film, region or substrate is referred to as being “on” or “connected to” another element, it can be directly on or directly connected to the other element, or intervening elements may also be present. In contrast, when an element is referred to as being “directly on” or “directly connected to” another element, there are no intervening elements present.

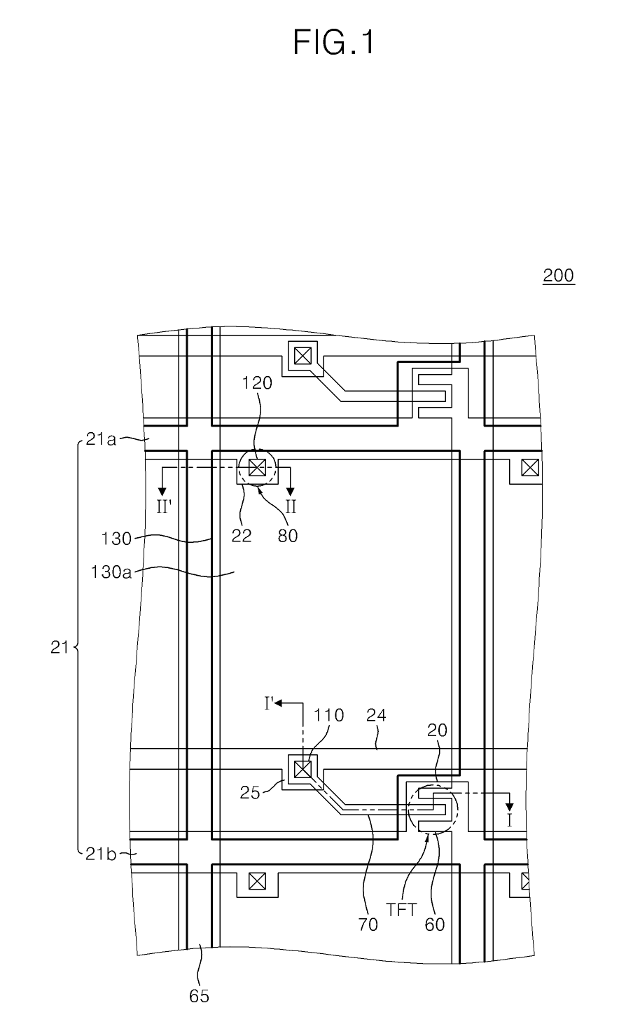

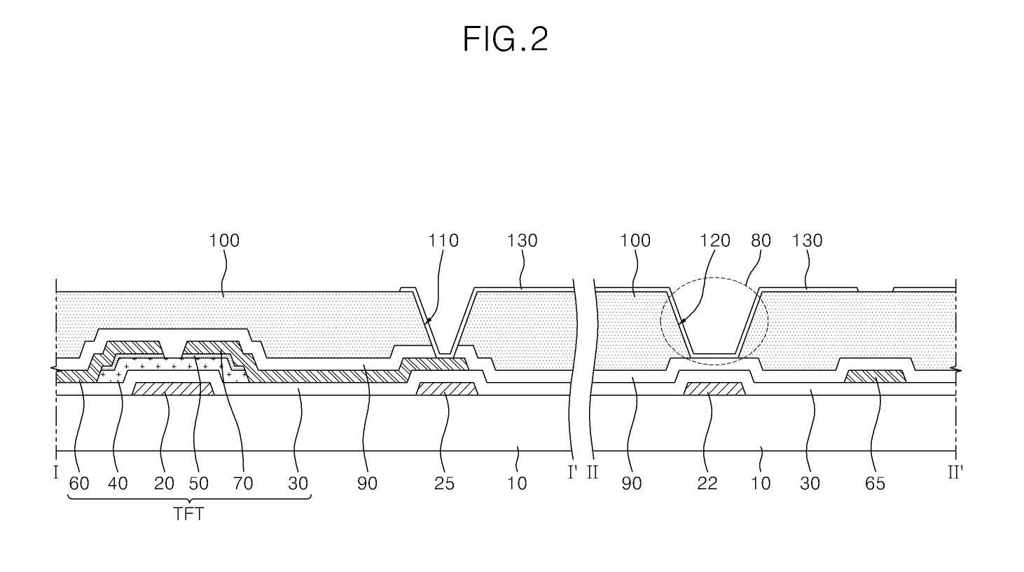

FIG. 1 is a plan view illustrating a TFT substrate of an LCD panel according to an exemplary embodiment of the present invention. FIG. 2 is a cross-sectional view taken along line I-I′ and line II-II′ of FIG. 1.

Referring to FIG. 1 and FIG. 2, a TFT substrate 200 includes gate lines 21 arranged on a lower substrate 10 in a first direction, data lines 65 arranged in a direction substantially perpendicular to and crossing with the gate lines 21, and TFTs arranged at crossing points of the gate lines 21 and the data lines 65. The gate lines 21 include a previous gate line 21a and a current gate line 21b. The TFT substrate 200 further includes a gate insulating layer 30 arranged on the lower substrate 10 to cover the gate line 21, an organic passivation layer 100 arranged on the lower substrate 10 to cover the TFT, a pixel electrode 130 connected to the TFT via a pixel contact hole 110, a repair portion 80 arranged where the pixel electrode 130 overlaps with the previous gate line 21a, and a repair hole 120 arranged in the organic passivation layer 100.

If a sub-pixel region 130a has a defect, the pixel electrode 130 in the defective sub-pixel region 130a and the previous gate line 21a are short-circuited using a laser. Specifically, the laser is used to connect the pixel electrode 130 in the defective sub-pixel region 130a and the previous gate line 21a.

The TFT substrate 200 is described below in more detail.

An insulating material such as transparent glass or plastic may be used as the lower substrate 10. The gate line 21 and the data line 65 are arranged on the lower substrate 10.

The gate line 21 supplies a scan signal, and the data line 65 supplies an image data signal. A gate insulating layer 30 is arranged between the gate line 21 and the data line 65.

A sub-pixel region 130a is enclosed by the gate lines 21 and the data lines 65. The TFTs are arranged at crossing points of the gate lines 21 and the data lines 65, and the TFTs are connected to the gate lines 21 and the data lines 65. The pixel electrode 130 is arranged in each sub-pixel region 130a and is connected to the TFT. A storage line 24 is arranged substantially parallel to the gate line 21, and a storage electrode 25 extends from the storage line 24.

Each TFT includes a gate electrode 20 extending from the gate line 21, a source electrode 60 extending from the data line 65, a drain electrode 70 connected to the pixel electrode 130, and a semiconductor layer 40 arranged on the gate insulating layer 30 to form a channel between the source electrode 60 and the drain electrode 70. The TFT may further include an ohmic contact layer 50 arranged on the semiconductor layer 40 for ohmic contact between the semiconductor layer 40 and the source electrode 60, and between the semiconductor layer 40 and the drain electrode 70. The TFT supplies the image data signal from the data line 65 to the pixel electrode 130 in response to the scan signal from the gate line 21.

The pixel electrode 130 is connected to the drain electrode 70 via the pixel contact hole 110, which penetrates the organic passivation layer 100. The pixel electrode 130 drives the liquid crystal layer to adjust light transmissivity by using a voltage difference between the pixel electrode 130 and a common electrode 340 (shown in FIG. 6) of a color filter substrate 300 (shown in FIG. 6) when the image data signal is supplied from the TFT. The pixel electrode 130 may be made of a transparent conductive material such as indium tin oxide (ITO) or indium zinc oxide (IZO). The organic passivation layer 100 may be made of an organic insulating material and may have a thickness of several micro meters (μm). The pixel electrode 130 is arranged to overlap with the gate lines 21 arranged on the upper side and the lower side of the pixel electrode 130 and the data lines 65 arranged on the right side and the left side of the pixel electrode 130, thereby increasing aperture ratio. In this instance, since the organic passivation layer 100 has a thickness of several micro meters (μm), a parasite capacitance formed between the pixel electrode 130 and the gate line 21 and a parasite capacitance formed between the pixel electrode 130 and the data line 65 may be small. Thus, the parasite capacitances may not interfere substantially with the image data signal to be applied to the pixel electrode 130.

However, the TFT may deteriorate due to a chemical reaction between the organic material and the semiconductor layer 40 when the organic passivation layer 100 is arranged between the source electrode 60 and the drain electrode 70. For example, a turn-off characteristic of the TFT may be degraded since the amplitude of an off current between the source electrode 60 and the drain electrode 70 becomes greater when a gate off voltage is applied to the TFT. In order to prevent the deterioration of the TFT, an inorganic passivation layer 90 is arranged over the TFT, the data line 65, and the gate insulating layer 30 to cover the TFT. The inorganic passivation layer 90 may be made of the same or substantially similar inorganic insulating material as the gate insulating layer 30.

The storage line 24 is arranged substantially parallel to the gate line 21 to supply a storage voltage. The storage electrode 25 extends from the storage line 24 to form a storage capacitor. The storage electrode 25 overlaps with the drain electrode 70. Since the total thickness of the gate insulating layer 30, the inorganic passivation layer 90, and the organic passivation layer 100 formed between the storage electrode 25 and the pixel electrode 130 is more than several micro meters (μm), the capacitance between the storage electrode 25 and the pixel electrode 130 may be small. In order to have improved storage capacitance, the drain electrode 70 may have an area substantially similar to the area of the storage electrode 25, and the storage electrode 25 is arranged to overlap with the drain electrode 70. As a result, the storage capacitance may be increased. The previous gate line 21a has a gate extending portion 22 that extends toward the sub-pixel region 130a.

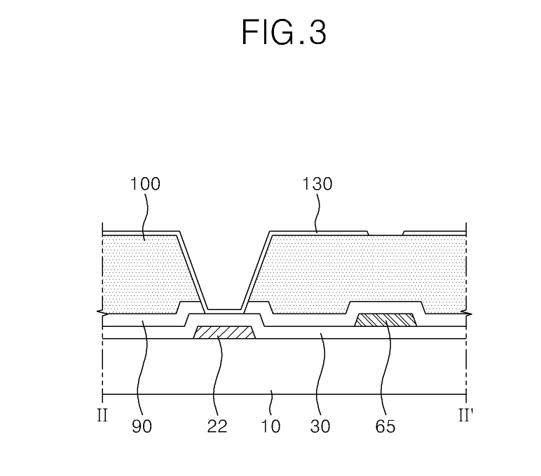

The repair portion 80 is arranged such that the gate extending portion 22 of the previous gate line 21a overlaps with the pixel electrode 130. That is, the repair portion 80 is arranged where the gate extending portion 22 of the previous gate line 21a overlaps with the pixel electrode 130 in a repair hole 120. Here, the repair hole 120 is arranged to penetrate a portion of the organic passivation layer 100 corresponding to the gate extending portion 22 while exposing a portion of the inorganic passivation layer 90, as shown in FIG. 2, or to penetrate the inorganic passivation layer 90 and the organic passivation layer 100 while exposing a portion of the gate insulating layer 30, as shown in FIG. 3. Thus, the risk of a repair defect is reduced since the previous gate line 21a and the pixel electrode 130 are not separated by a thick organic passivation layer 100, unlike in the conventional LCD panel.

The gate extending portion 22 may prevent the previous gate line 21a having a small width from being disconnected from the pixel electrode 130 after a repair process is performed, and may also increase the size of a contact area between the pixel electrode 130 and the previous gate line 21a, thereby preventing a repair defect.

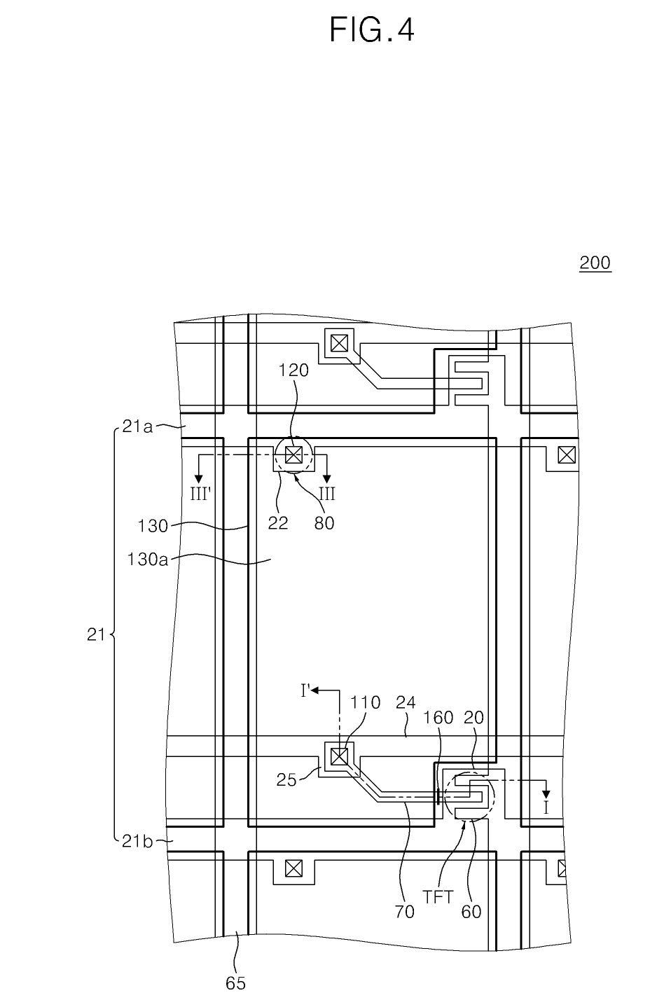

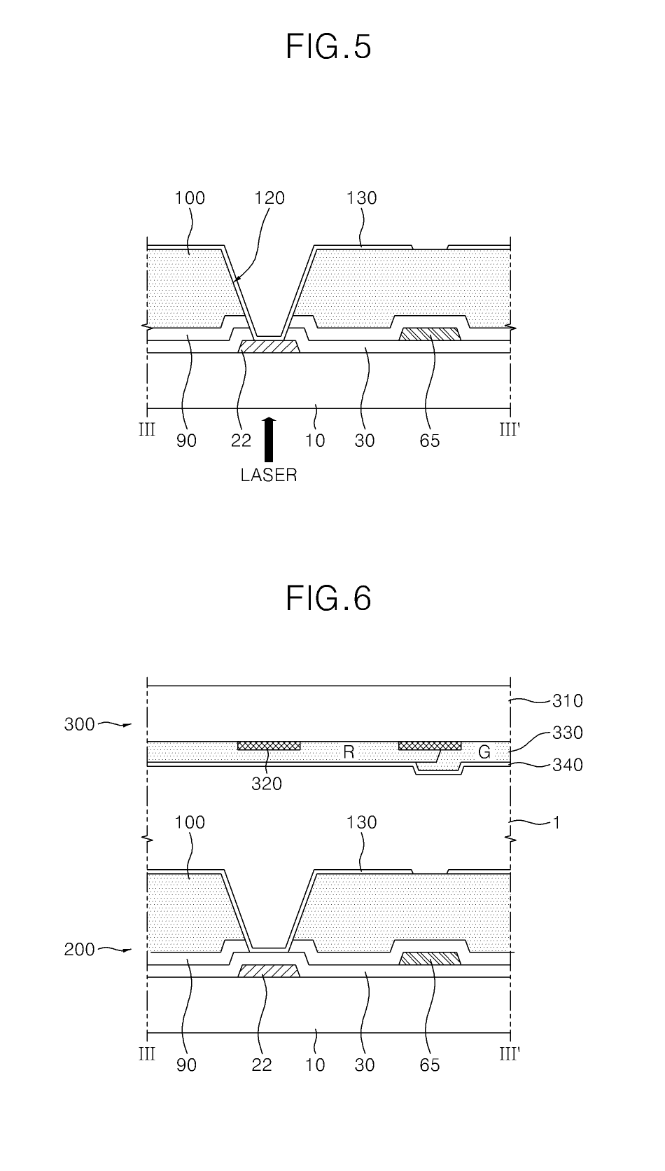

FIG. 4 is a plan view illustrating the TFT substrate of FIG. 1 after a repair process according to the exemplary embodiment of the present invention. FIG. 5 is a cross-sectional view taken along line III-III′ of FIG. 4.

Referring to FIG. 4 and FIG. 5, if a defect occurs in a sub-pixel, the repair process may be performed such that the repair portion 80 is short-circuited by a laser beam and the drain electrode 70 is disconnected.

In more detail, the gate extending portion 22 and the pixel electrode 130 of the repair portion 80 are short-circuited or connected to each other by irradiating a laser toward a portion of the lower substrate 10 corresponding to the repair portion 80, and the drain electrode 70 is disconnected from the pixel electrode 130 along a cut line 160 by laser cutting. The scan signal is supplied to the gate electrode 20 of the TFT of the corresponding pixel, but the image data signal is not applied to the pixel electrode 130 since the drain electrode 70 is cut along cut line 160. Instead, a signal having a gate-off voltage and supplied to the previous gate line 21a is applied to the pixel electrode 130 through the gate extending portion 22. Therefore, the gate-off voltage is charged in the corresponding sub pixel. As a result, the corresponding sub-pixel displays black.

FIG. 6 is a cross-sectional view illustrating an LCD panel with the TFT substrate of FIG. 1 according to an exemplary embodiment of the present invention. FIG. 6 shows the LCD panel focusing on the repair portion 80.

Referring to FIG. 6, the LCD panel includes the TFT substrate 200 and the color filter substrate 300. The color filter substrate 300 includes an upper substrate 310, and black matrixes 320 arranged on portions of the upper substrate 310 corresponding to the gate line 21, the data line 65 and the TFT. The color filter substrate 300 also includes color filters 330 including an R color filter, a G color filter, and a B color filter arranged so the ends of adjacent color filters overlap with each other, and a common electrode 340 arranged over the upper substrate 310 to cover the color filters 330. A liquid crystal layer 1 is arranged between the TFT substrate 200 and the color filter substrate 300.

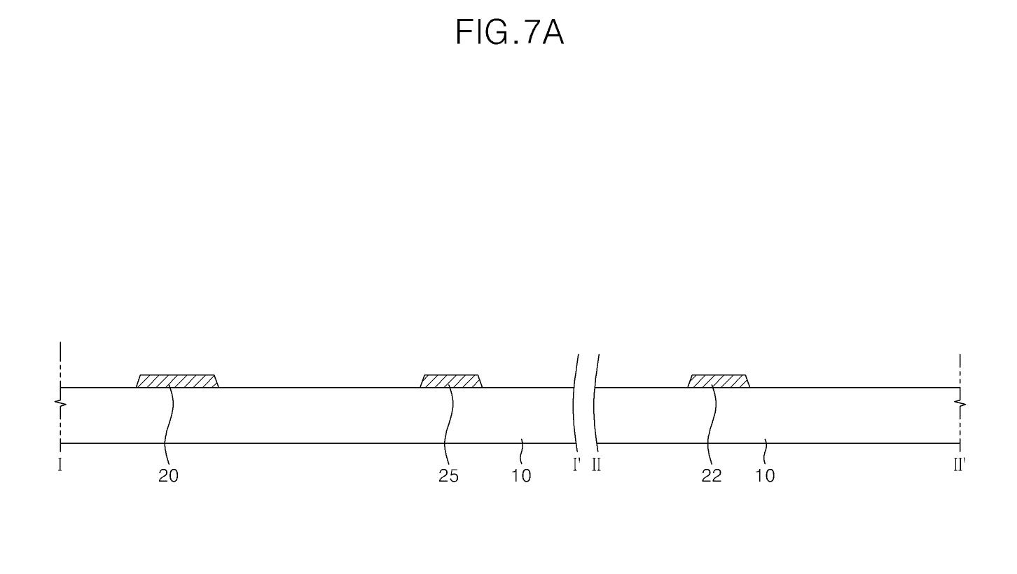

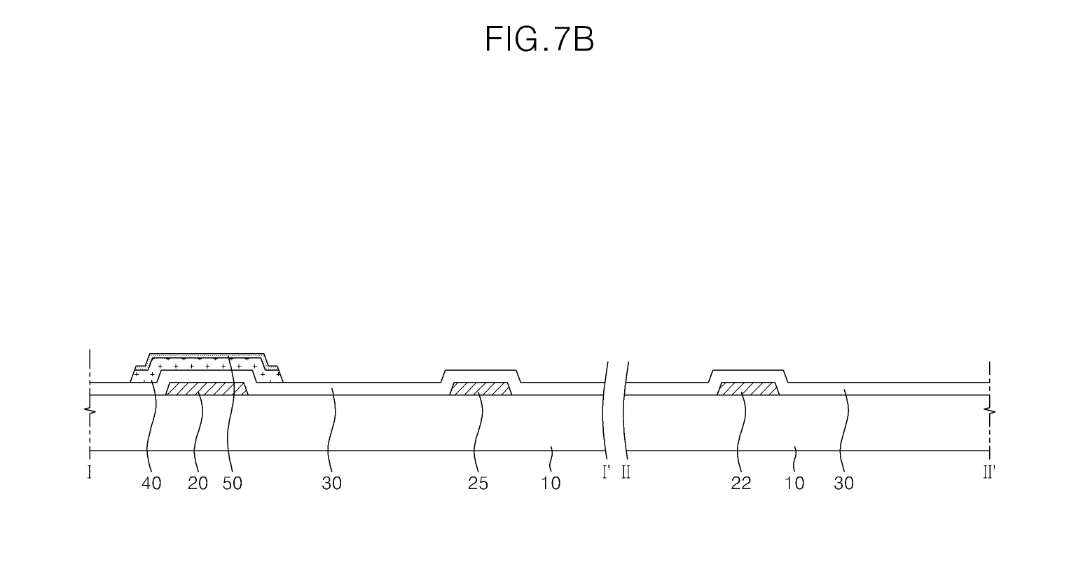

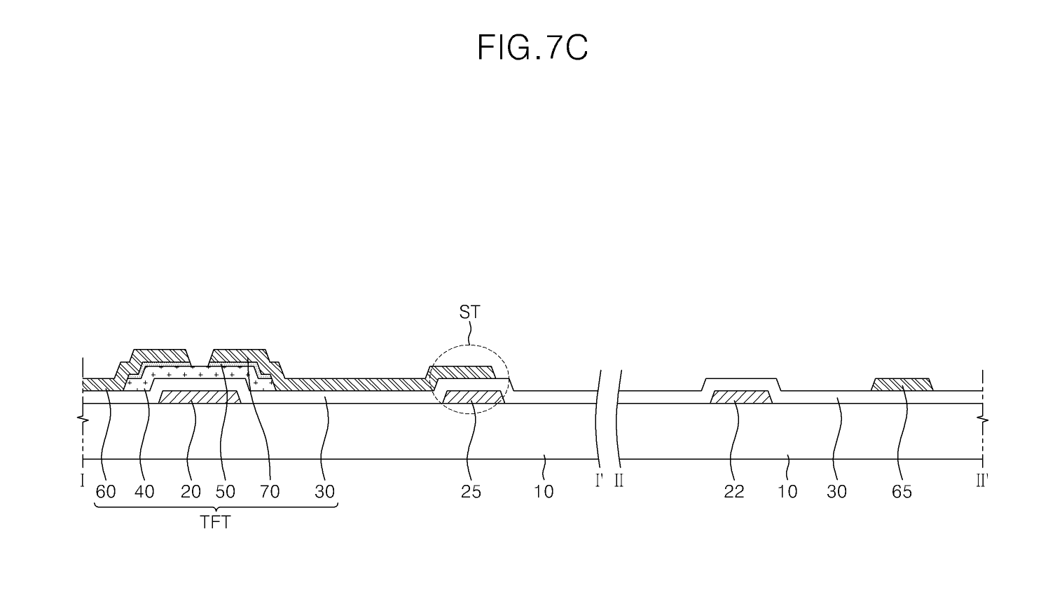

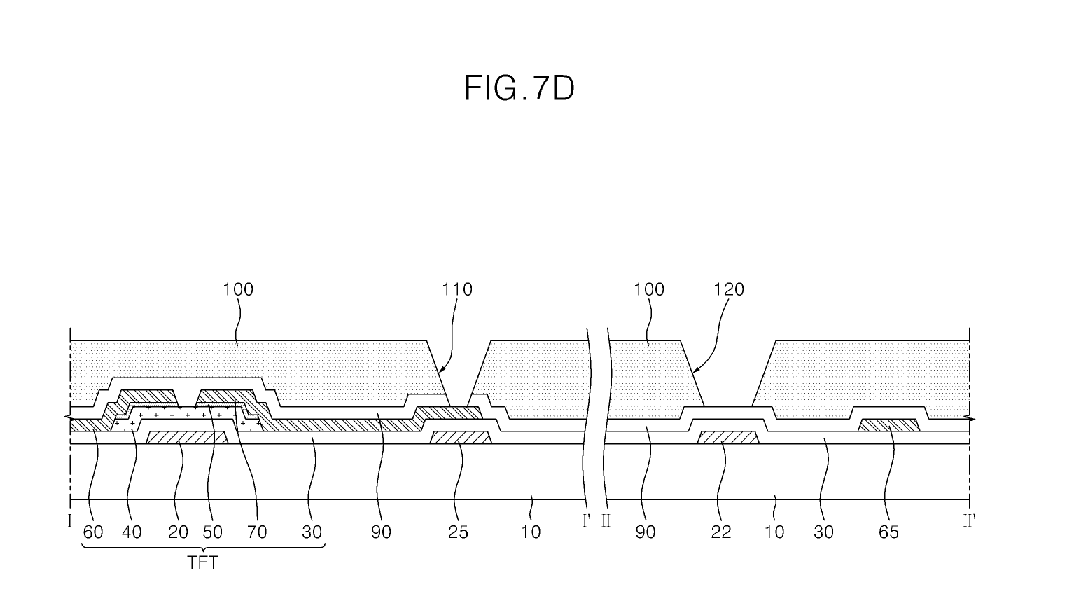

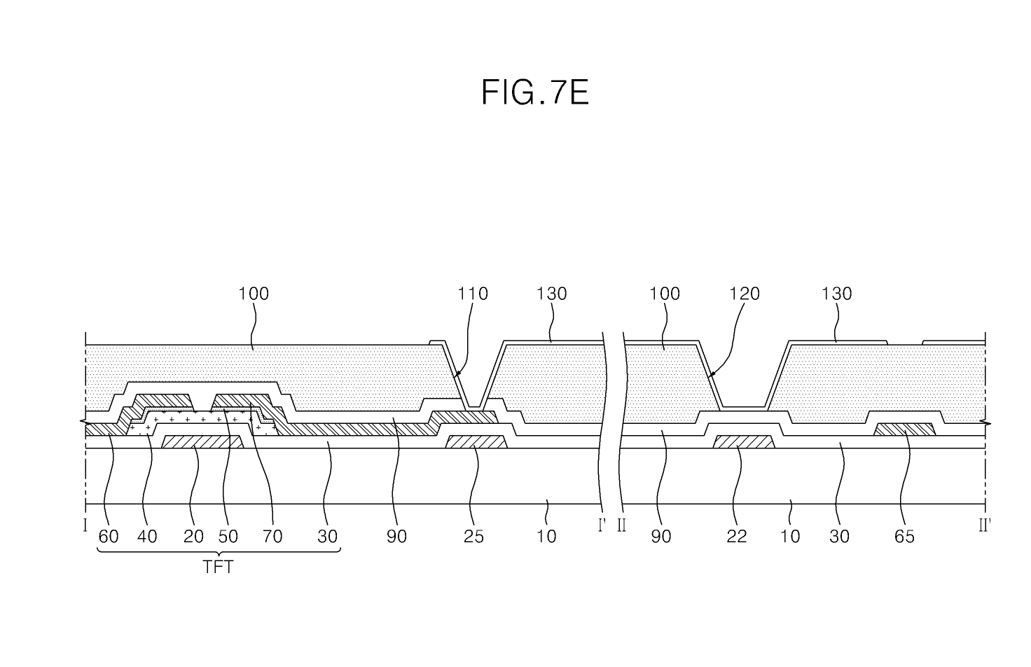

FIG. 7A, FIG. 7B, FIG. 7C, FIG. 7D, and FIG. 7E are cross-sectional views illustrating a process of fabricating the TFT substrate of FIG. 1. The TFT substrate according to the exemplary embodiment of the present invention may be fabricated by using five masks.

FIG. 7A shows a first mask process of fabricating the TFT substrate according to the exemplary embodiment of the present invention.

Referring to FIG. 7A, a first conductive pattern group including the gate electrode 20, the gate line 21, the gate extending portion 22, the storage line 24, and the storage electrode 25 is formed on the lower substrate 10 using the first mask process.

In more detail, a first conductive layer is deposited on the lower substrate 10 by using, for example, a sputtering technique. The first conductive layer may have a single-layer structure formed of aluminum (Al), chromium (Cr), copper (Cu), molybdenum (Mo), or tungsten (W), or a multi-layer structure formed of a combination thereof. The first conductive layer is patterned through a photolithography process using a first mask and an etching process to thereby form the first conductive pattern group including the gate electrode 20, the gate line 21, the gate extending portion 22, the storage line 24, and the storage electrode 25. Here, the gate extending portion 22 extends towards the next sub-pixel region.

FIG. 7B shows a second mask process of fabricating the TFT substrate according to the exemplary embodiment of the present invention.

Referring to FIG. 7B, the gate insulating layer 30, the semiconductor layer 40, and the ohmic contact layer 50 are formed on the lower substrate 10 having the first conductive pattern group using the second mask process.

In more detail, the gate insulating layer 30, an amorphous silicon layer, and a doped amorphous silicon layer are sequentially deposited on the lower substrate 10 having the first conductive pattern group by using a chemical vapor deposition (“CVD”) technique or a plasma enhanced chemical vapor deposition (“PECVD”) technique. The amorphous silicon layer and the doped amorphous silicon layer may be patterned by a photolithography process using a second mask and an etching process to thereby form the semiconductor layer 40 and the ohmic contact layer 50. Here, the gate insulating layer 30 may be formed of an inorganic insulating material such as silicon nitride (SiNx) or silicon oxide (SiOx).

FIG. 7C shows a third mask process of fabricating the TFT substrate according to the exemplary embodiment of the present invention.

Referring to FIG. 7C, a second conductive pattern group including the source electrode 60, the data line 65, and the drain electrode 70 is formed on the TFT substrate shown in FIG. 7B, and specifically on the gate insulating layer 30, the semiconductor layer 40, and the ohmic contact layer 50 using the third mask process.

More specifically, a second conductive layer is deposited by using, for example, a sputtering technique and then patterned into the second conductive pattern group including the source electrode 60, the data line 65, and the drain electrode 70 through a photolithography process using a third mask and an etching process. The second conductive layer may have a single-layer structure formed of Al, Cr, Cu, Mo, or W, or a multi-layer structure formed of a combination thereof. The data line 65 is formed on the gate insulating layer 30 to cross with the gate line 21. The drain electrode 70 is formed on the gate insulating layer 30 while covering a first end of the semiconductor layer 40 and the ohmic contact layer 50. The drain electrode 70 is also formed to overlap with the storage electrode 25 to thereby form a storage capacitor ST. The source electrode 60 extends from the data line 65 and is formed on the gate insulating layer 30 while covering a second end of the semiconductor layer 40 and the ohmic contact layer 50.

FIG. 7D shows a fourth mask process of fabricating the TFT substrate according to the exemplary embodiment of the present invention.

Referring to FIG. 7D, the organic passivation layer 100 having the pixel contact hole 110 and the repair hole 120 formed therein is formed over the lower substrate 10 using the fourth mask process.

In more detail, the organic passivation layer 100 is formed over the lower substrate 10 having the second conductive pattern group by using a deposition technique such as a CVD technique, a PECVD technique, or a spin coating technique. The organic passivation layer 100 is subjected to a photolithography process using a fourth mask and an etching process to form the pixel contact hole 110, which exposes a portion of the drain electrode 70, and the repair hole 120, which exposes a portion of the gate insulating layer 30. The pixel contact hole 110 may be formed where the drain electrode 70 and the storage electrode 25 overlap.

Before forming the organic passivation layer 100, the inorganic passivation layer 90 made of an inorganic insulating material such as SiNx or SiOx may be optionally formed. That is, in order to prevent the deterioration of the TFT, the inorganic passivation layer 90 may be formed over the lower substrate 10. In this instance, the pixel contact hole 110 is formed to penetrate the inorganic passivation layer 90 and the organic passivation layer 100, and the repair hole 120 is formed to expose a portion of the inorganic passivation layer 90 or to penetrate the inorganic passivation layer 90 and the organic passivation layer 100. Here, in order to expose a portion of the inorganic passivation layer 90, the pixel contact hole 110 and the repair hole 120 may be patterned by using a slit mask or a half-tone mask.

FIG. 7E shows a fifth mask process of fabricating the TFT substrate according to the exemplary embodiment of the present invention.

Referring to FIG. 7E, the pixel electrode 130 is formed on the organic passivation layer 100 using the fifth mask process.

In more detail, a transparent conductive layer is deposited on the organic passivation layer 100 by using, for example, a sputtering technique. The transparent conductive layer is then patterned through a photolithography process using a fifth mask and an etching process to thereby form the pixel electrode 130. The transparent conductive layer may be made of a transparent conductive material such ITO, IZO or TO. The pixel electrode 130 is connected to the drain electrode 70 via the pixel contact hole 110.

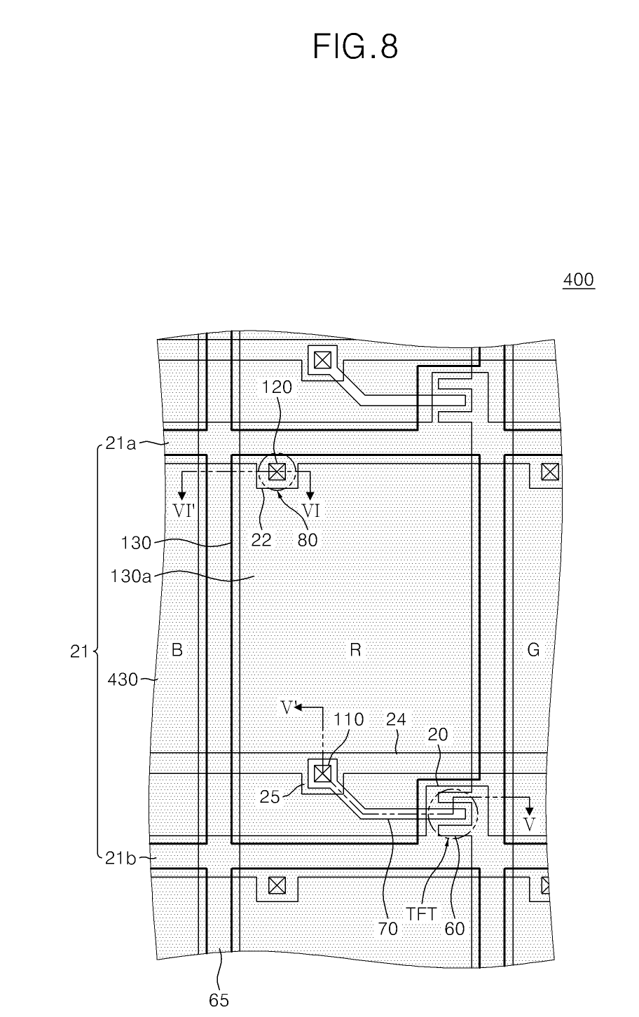

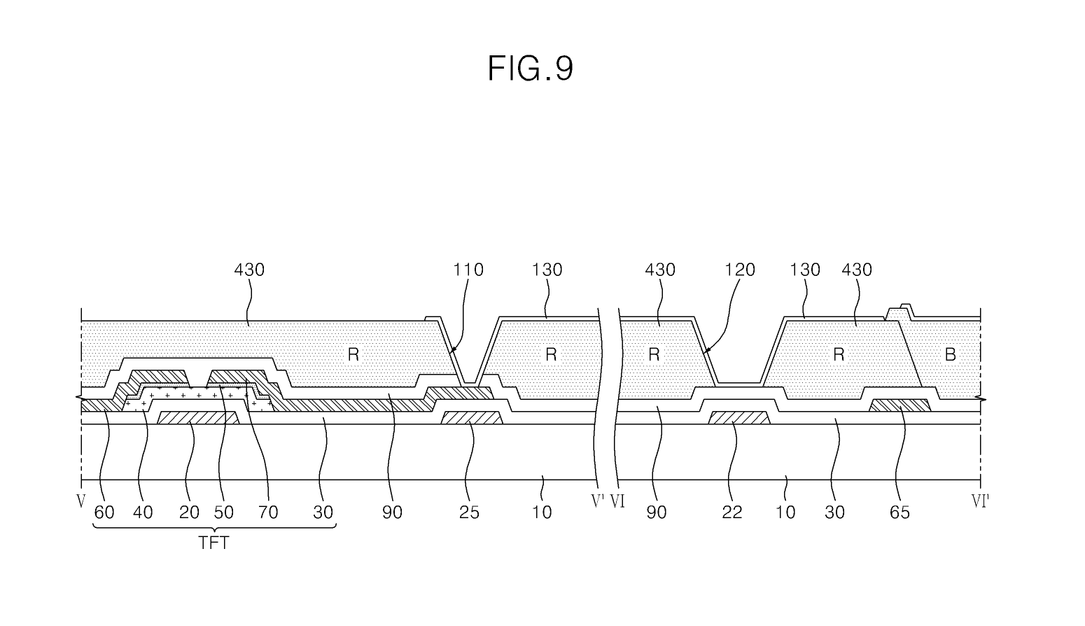

FIG. 8 is a plan view illustrating a color filter on TFT array (“COA”) substrate of an LCD panel according to another exemplary embodiment of the present invention. FIG. 9 is a cross-sectional view taken along line V-V′ and line VI-VI′ of FIG. 8. A COA substrate 400 of FIG. 8 and FIG. 9 may have a similar configuration as the TFT substrate 200 of FIG. 1 and FIG. 2 except that color filters 430 may be arranged on the lower substrate 10 instead of the organic passivation layer 100 of FIG. 2 to cover the TFTs.

On the COA substrate 400, the gate line 21 and the data line 65 are arranged to cross with each other and the gate insulating layer 30 is interposed therebetween. A sub-pixel region 130a is enclosed by the gate lines 21 and the data lines 65. The TFT is formed at a crossing point of the gate lines 21 and the data lines 65, and the pixel electrode 130 is connected to the TFT.

The repair portion 80 having the repair hole 120 is arranged such that the gate extending portion 22 and the pixel electrode 130 overlap with each other. The repair hole 120 is arranged to penetrate the color filters 430 while exposing either the inorganic passivation layer 90 or the gate insulating layer 30.

More specifically, the TFT includes the gate electrode 20 extending from the gate line 21, the source electrode 60 extending from the data line 65, the drain electrode 70 connected to the pixel electrode 130, the semiconductor layer 40 arranged on a portion of the gate insulating layer 30 between the source electrode 60 and the drain electrode 70, and the ohmic contact layer 50 arranged on the semiconductor layer 40 for ohmic contact between the semiconductor layer 40 and the source electrode 60 and the drain electrode 70. The storage line 24 is arranged substantially parallel with the gate line 21, and the storage electrode 25 extends from the storage line 24. The drain electrode 70 and the storage electrode 25 overlap with the gate insulating layer 30 interposed therebetween to thereby form the storage capacitor. The drain electrode 70 is also connected to the pixel electrode 130 via the pixel contact hole 110. The storage capacitor serves to stably keep a data signal charged in the pixel electrode 130.

The inorganic passivation layer 90 is formed to protect the data line 65 and the TFT. The R, G and B color filters 430 are arranged on the inorganic passivation layer 90 in corresponding pixel regions. Two adjacent color filters 430 partially overlap with each other at a location corresponding to the data line 65. The color filters 430 may be made of a photoresist or color resin with corresponding R, G and B pigments mixed therewith, and thus the color filters 430 may serve as an organic passivation layer. Each of the R, G and B color filters 430 may be arranged in a dot form of a sub-pixel unit or a stripe form of a column line unit.

The pixel electrode 130 is arranged on the R, G or B color filter 430 corresponding to the sub-pixel and is connected to the drain electrode 70 via the pixel contact hole 110 which penetrates the color filters 430 and the inorganic passivation layer 90. The pixel electrode 130 is arranged to overlap with the gate lines 21 arranged on the upper side and the lower side of the pixel electrode 130 and the data lines 65 arranged on the right side and the left side of the pixel electrode 130, thereby increasing aperture ratio.

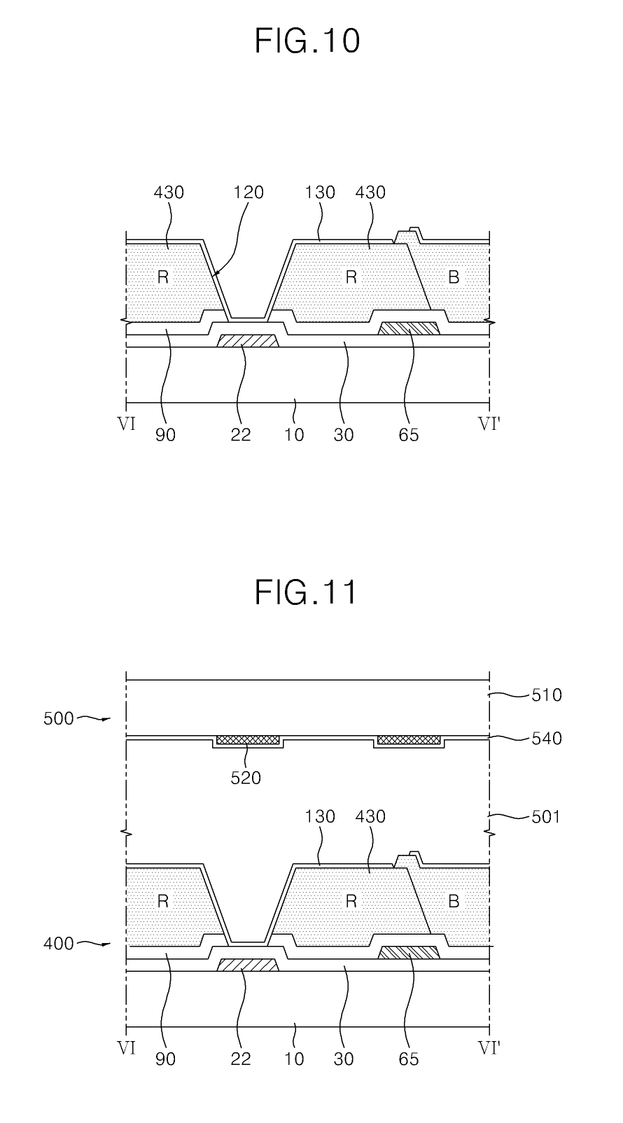

The repair portion 80 is arranged so the pixel electrode 130 overlaps with the gate extending portion 22, and the gate insulating layer 30 and the inorganic passivation layer 90 are interposed therebetween. The repair hole 120 is arranged in the color filter 430 corresponding to the gate extending portion 22 to expose a portion of the inorganic passivation layer 90. Alternatively, as illustrated in FIG. 10, the repair hole 120 may expose a portion of the gate insulating layer 30 corresponding to the gate extending portion 22.

Due to the repair hole 120 of the repair portion 80 described above, the distance between the gate extending portion 22 and the pixel electrode 130 is reduced. Accordingly, the repairing process of repairing the defective pixel can be carried out more easily.

FIG. 11 is a cross-sectional view illustrating the LCD panel with the COA substrate of FIG. 8 according to another exemplary embodiment of the present invention. Referring to FIG. 11, the LCD panel includes the COA substrate 400 and an upper substrate 500 with the liquid crystal layer 501 interposed therebetween. The COA substrate 400 has the configuration described above. The upper substrate 500 includes a substrate 510, black matrixes 520 formed on portions of the substrate 510 corresponding with the gate lines 21, the data lines 65, and the TFT to prevent light from being leaked, and a common electrode 540 arranged on the substrate 510 to cover the black matrix 520.

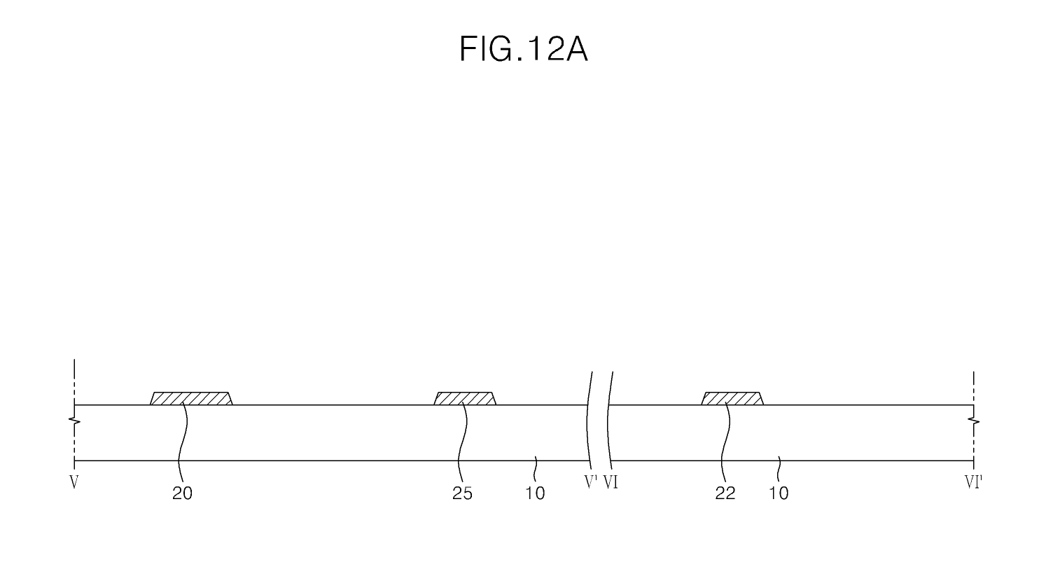

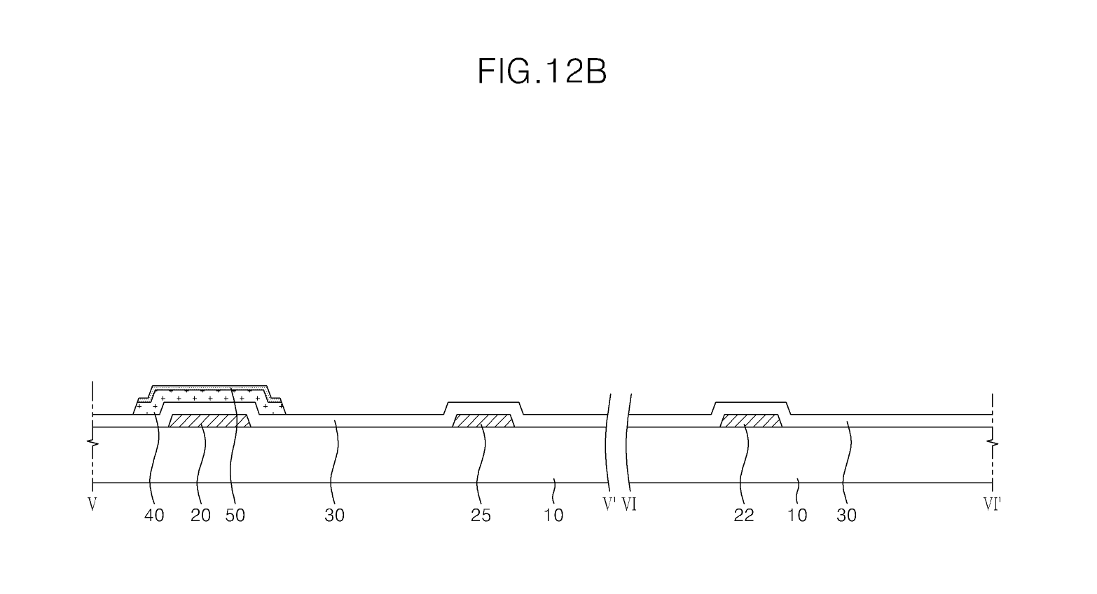

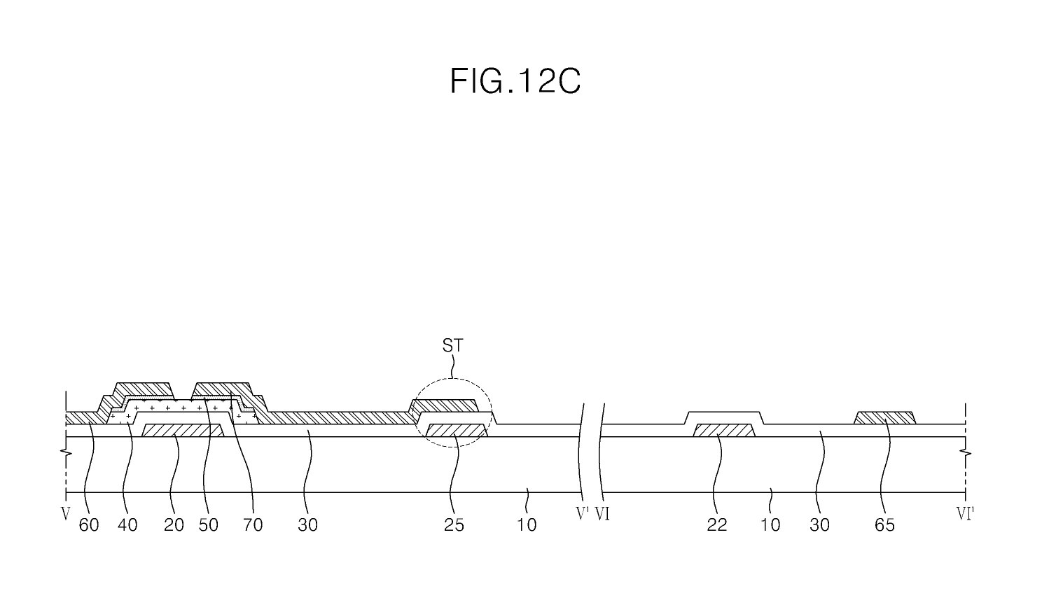

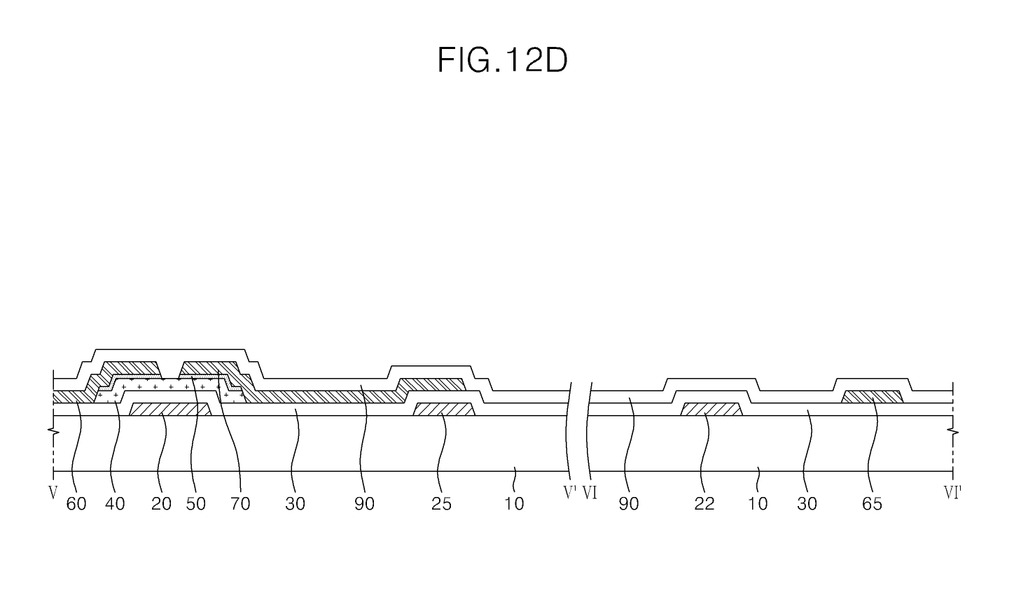

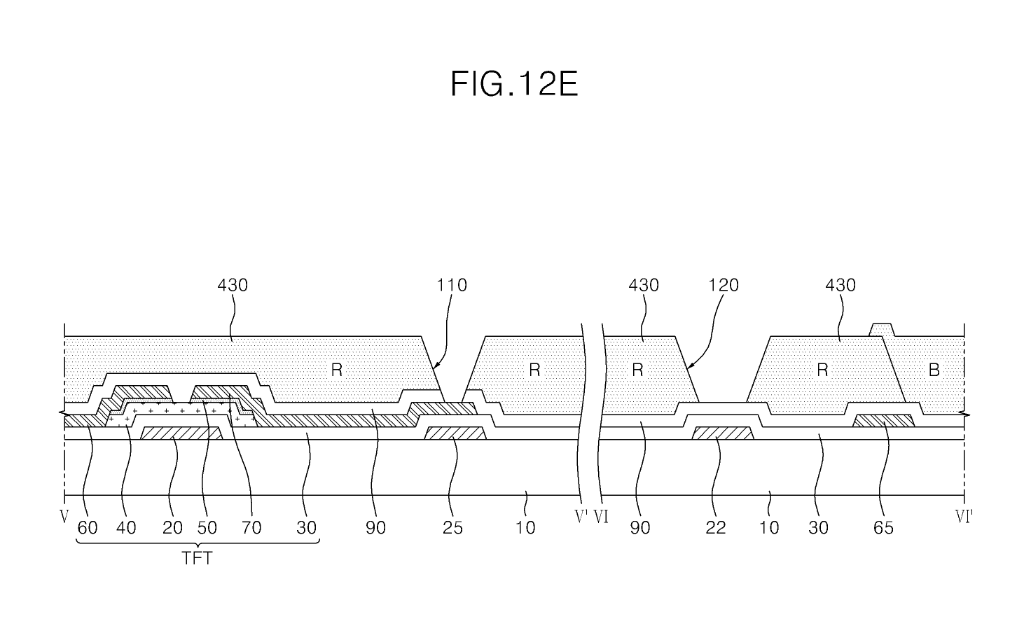

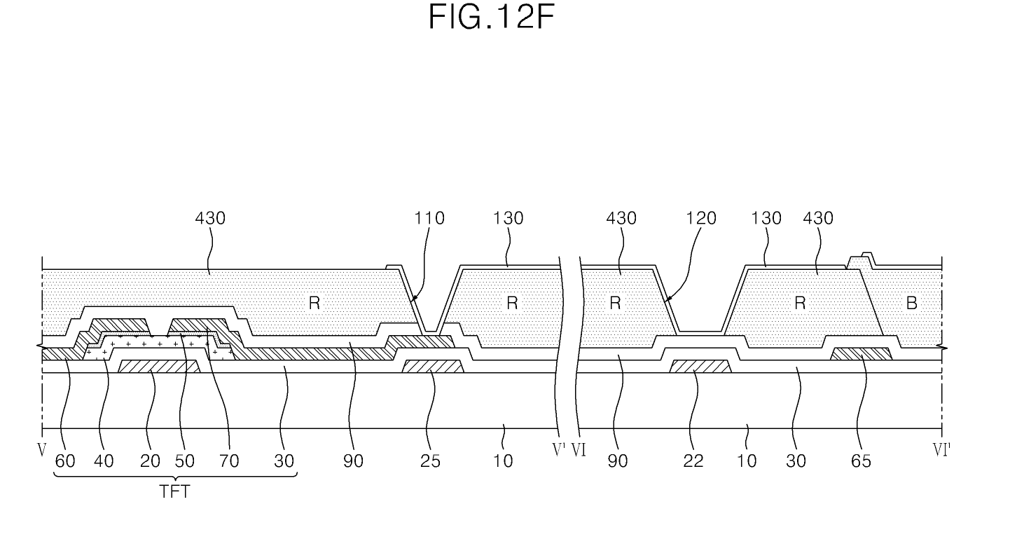

FIG. 12A, FIG. 12B, FIG. 12C, FIG. 12D, FIG. 12E, and FIG. 12F are cross-sectional views illustrating a process of fabricating the COA substrate of FIG. 8.

FIG. 12A shows a first mask process of fabricating the COA substrate 400 according to another exemplary embodiment of the present invention.

Referring to FIG. 12A, a first conductive pattern group including the gate electrode 20, the gate line 21 (shown in FIG. 8), the gate extending portion 22, the storage line 24, and the storage electrode 25 is formed on the lower substrate 10 using the first mask process.

In more detail, a first conductive layer is deposited on the lower substrate 10 by using, for example, a sputtering technique. The first conductive layer may have a single-layer structure formed of Al, Cr, Cu, Mo, or W, or a multi-layer structure formed of a combination thereof. The first conductive layer is patterned through a photolithography process using a first mask and an etching process to thereby form a first conductive pattern group including the gate electrode 20, the gate line 21, the gate extending portion 22, the storage line 24, and the storage electrode 25. Here, the gate extending portion 22 extends towards the next sub-pixel region.

FIG. 12B shows a second mask process of fabricating the COA substrate according to another exemplary embodiment of the present invention.

Referring to FIG. 12B, the gate insulating layer 30, the semiconductor layer 40, and the ohmic contact layer 50 are formed on the lower substrate 10 having the first conductive pattern group through the second mask process.

In more detail, the gate insulating layer 30, an amorphous silicon layer, and a doped amorphous silicon layer are sequentially deposited on the lower substrate 10 having the first conductive pattern group by using a CVD technique or a PECVD technique. The amorphous silicon layer and the doped amorphous silicon layer are patterned by a photolithography process using a second mask and an etching process to thereby form the semiconductor layer 40 and the ohmic contact layer 50. Here, the gate insulating layer 30 may be made of an inorganic insulating material such as SiNx or SiOx.

FIG. 12C shows a third mask process of fabricating the COA substrate according to another exemplary embodiment of the present invention.

Referring to FIG. 12C, a second conductive pattern group including the source electrode 60, the data line 65 and the drain electrode 70 is formed on the COA substrate 400 of FIG. 12B, including the gate insulating layer 30, the semiconductor layer 40, and the ohmic contact layer 50 using the third mask process.

More specifically, a second conductive layer is deposited by using, for example, a sputtering technique and then patterned into the second conductive pattern group including the source electrode 60, the data line 65, and the drain electrode 70 through a photolithography process using a third mask and an etching process. The second conductive layer may have a single-layer structure formed of Al, Cr, Cu, Mo, or W, or a multi-layer structure formed of a combination thereof. The data line 65 is formed on the gate insulating layer 30 to cross with the gate line 21. The drain electrode 70 is formed on the gate insulating layer 30 while covering a first end of the semiconductor layer 40 and the ohmic contact layer 50. The drain electrode 70 is also formed to overlap with the storage electrode 25 to thereby form the storage capacitor. The source electrode 60 extends from the data line 65 and is formed on the gate insulating layer 30 while covering the second end of the semiconductor layer 40 and the ohmic contact layer 50.

FIG. 12D shows a fourth mask process of fabricating the COA substrate according to another exemplary embodiment of the present invention.

Referring to FIG. 12D, the inorganic passivation layer 90 is formed over the lower substrate 10 having the second conductive pattern group using a fourth mask process. The inorganic passivation layer 90 is formed on the gate insulating layer 30 including the source electrode 60 and the drain electrode 70 by using a CVD or PECVD technique. The inorganic passivation layer 90 may be made of the same or a substantially similar inorganic insulating material as the gate insulating layer 30.

FIG. 12E shows fifth to seventh mask processes of fabricating the COA substrate according to another exemplary embodiment of the present invention.

Referring to FIG. 12E, the R, G and B color filters 430 are formed on portions of the inorganic passivation layer 90 corresponding to respective sub-pixel regions using a fifth mask process, a sixth mask process, and a seventh mask process. In more detail, a red (R) photoresist is coated on the inorganic passivation layer 90 and then patterned through a photolithography process using a fifth mask. Thereafter, the G and B color filters 430 are sequentially formed on the inorganic passivation layer 90 by using a six mask and a seventh mask in the same or substantially similar way as the R color filter 430. The R, G and B color filters 430 may be formed in a dot form of a sub-pixel unit or a stripe form of a column line unit. Here, the pixel contact hole 110 is formed in the color filter 430. That is, when the color filters 430 are formed, the pixel contact hole 110 is formed to penetrate the color filters 430 and the inorganic passivation layer 90 while exposing a portion of the drain electrode 65. The repair hole 120 is formed to penetrate the color filter 430 while exposing a portion of the inorganic passivation layer 90 corresponding to the gate extending portion 22, or to penetrate the color filter 430 and the inorganic passivation layer 90 while exposing a portion of the gate insulating layer 30 similar to the structure shown in FIG. 10.

FIG. 12F shows an eighth mask process of fabricating the COA substrate according to another exemplary embodiment of the present invention.

Referring to FIG. 12F, the pixel electrode 130 connected to the drain electrode 70 via the contact hole 110 is formed on the color filter 430 through the eighth mask process. A transparent conductive material such ITO, IZO, TO, or indium tin zinc oxide (ITZO) is deposited on the color filter 430 by using, for example, a sputtering technique. The transparent conductive material is then patterned through a photolithography process using an eighth mask and an etching process to form the pixel electrode 130 connected to the drain electrode 70 via the contact hole 110. The pixel electrode 130 is arranged to overlap with the gate lines 21 arranged at the upper side and the lower side of the pixel electrode 130 and the data lines 65 arranged at the right side and the left side of the pixel electrode 130, thereby increasing aperture ratio.

In another exemplary embodiment of the present invention, the COA substrate 400 of the LCD panel is fabricated using eight mask processes as described above, and the aperture ratio is increased by the color filter 430 made of an inorganic material.

In addition, the previous gate line 21a and the pixel electrode 130 can be reliably short-circuited by a laser beam due to the repair hole 120 of the repair portion 80 formed to penetrate the color filter 430, which serves as the organic insulating layer.

Further, the COA substrate 400 of FIG. 8 may be fabricated through a seven mask process. For example, the second mask process and the third mask process can be performed by a single mask process, so that the number of mask processes is reduced, leading to a reduced processing time.

As described above, the LCD panel and the method for fabricating the same according to the present invention can reduce the risk of a repair defect. Specifically, the previous gate line and the pixel electrode can be more reliably short-circuited by a laser beam since the repair hole formed to penetrate the organic insulating layer decreases the separation between the pixel electrode and the previous gate line. In addition, the repair process can be performed easily since the gate extending portion extending from the gate line increases a repair area.

The LCD panel and the method for fabricating the same according to the present invention can be applied to the COA substrate.

In above descriptions, the TFT substrate is applied to an LCD panel. However, the TFT substrate may be applied to for example, an organic light emitting diode (OLED) display.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A liquid crystal display panel, comprising:
a first substrate;
a second substrate facing the first substrate; and
a liquid crystal layer interposed between the first substrate and the second substrate,
wherein the second substrate comprises:
a gate line arranged on the second substrate;
a data line crossing with the gate line, a gate insulating layer being interposed between the gate line and the data line;
a thin film transistor connected to the gate line and the data line at a crossing point of the gate line and the data line;
an organic passivation layer arranged on the thin film transistor;
a pixel electrode arranged in the sub-pixel region and connected to the thin film transistor via a pixel contact hole penetrating the organic passivation layer;
a repair portion comprising a region where the pixel electrode overlaps with a previous gate line; and
a repair hole arranged in the repair portion to penetrate the organic passivation layer.

2. The liquid crystal display panel of claim 1, wherein the first substrate includes a black matrix defining a sub pixel region.

3. The liquid crystal display panel of claim 2, wherein the second substrate further comprises:
a gate extending portion extending from the previous gate line toward the sub-pixel region,
wherein the repair hole corresponds to the gate extending portion.

4. The liquid crystal display panel of claim 3, wherein the second substrate further comprises:
an inorganic passivation layer arranged below the organic passivation layer,
wherein the pixel contact hole penetrates the inorganic passivation layer, and the repair hole exposes the inorganic passivation layer.

5. The liquid crystal display panel of claim 4, wherein the second substrate further comprises:
a storage line arranged substantially parallel with the gate line to supply a storage voltage; and
a storage electrode extending from the storage line to overlap with a drain electrode of the thin film transistor.

6. The liquid crystal display panel of claim 5, wherein the pixel electrode partially overlaps with the data line.

7. The liquid crystal display panel of claim 6, wherein the first substrate further comprises:
a color filter arranged in the sub-pixel region; and
a common electrode covering the color filter.

8. The liquid crystal display panel of claim 1, wherein the organic passivation layer comprises:
a color filter arranged in the sub-pixel region,
wherein two color filters in adjacent sub-pixel regions partially overlap with each other at a location corresponding to the data line.

9. The liquid crystal display panel of claim 8, wherein the second substrate further comprises:
a gate extending portion extending from the previous gate line toward the sub-pixel region,
wherein the repair hole corresponds to the gate extending portion.

10. The liquid crystal display panel of claim 9, wherein the second substrate further comprises:
an inorganic passivation layer arranged below the color filter,
wherein the pixel contact hole penetrates the inorganic passivation layer, and the repair hole penetrates the color filter to expose the inorganic passivation layer.

11. The liquid crystal display panel of claim 10, wherein the second substrate further comprises:
a storage line arranged substantially parallel with the gate line to supply a storage voltage; and
a storage electrode extending from the storage line to overlap with a drain electrode of the thin film transistor.

12. The liquid crystal display panel of claim 10, wherein the first substrate further comprises a common electrode covering the black matrix.

13. The liquid crystal display panel of claim 3, wherein the second substrate further comprises:
an inorganic passivation layer arranged below the organic passivation layer,
wherein the pixel contact hole penetrates the inorganic passivation layer, and the repair hole penetrates the inorganic passivation layer to expose the gate insulating layer.

14. The liquid crystal display panel of claim 9, wherein the second substrate further comprises:
an inorganic passivation layer arranged below the color filter,
wherein the pixel contact hole penetrates the inorganic passivation layer, and the repair hole penetrates the inorganic passivation layer to expose the gate insulating layer.

15. A method for fabricating a liquid crystal display panel, comprising:
preparing a first substrate including a black matrix defining a sub-pixel region;
preparing a second substrate to face the first substrate; and
interposing a liquid crystal layer between the first substrate and the second substrate,
wherein preparing the second substrate comprises:
forming a gate line on the second substrate;
forming a gate insulating layer on the gate line;
forming a data line to cross with the gate line, the gate insulating layer being interposed between the gate line and the data line;
forming a thin film transistor connected to the gate line and the data line at a crossing point of the gate line and the data line;
forming an organic passivation layer on the thin film transistor, the organic passivation layer including a pixel contact hole exposing a portion of a drain electrode of the thin film transistor;
forming a pixel electrode on the sub-pixel region and connecting the pixel electrode to the thin film transistor via the pixel contact hole;
forming a repair portion where the pixel electrode overlaps with a previous gate line; and
forming a repair hole in the repair portion to penetrate the organic passivation layer.

16. The method of claim 15, further comprising:
forming a gate extending portion extending from the previous gate line toward the sub-pixel region,
wherein the repair hole corresponds to the gate extending portion.

17. The method of claim 16, further comprising:
forming an inorganic passivation layer on the data line and the thin film transistor.

18. The method of claim 17, wherein forming the gate line further comprises:
forming a storage line substantially parallel with the gate line; and
forming a storage electrode extending from the storage line to overlap with the drain electrode.

19. The method of claim 18, wherein preparing the first substrate further comprises:
forming a color filter on the sub-pixel region; and
forming a common electrode on the color filter.

20. The method of claim 15, wherein the organic passivation layer comprises a color filter.

21. The method of claim 20, further comprising:
forming an inorganic passivation layer on the data line and the thin film transistor,
wherein the pixel contact hole penetrates the inorganic passivation layer, and the repair hole exposes the inorganic passivation layer.

22. The method of claim 21, wherein forming the gate line further comprises:
forming a storage line substantially parallel with the gate line; and
forming a storage electrode extending from the storage line to overlap with the drain electrode.

23. The method of claim 22, wherein preparing the first substrate further comprises forming a common electrode on the black matrix.

24. A thin film transistor substrate, comprising,
a substrate;
a gate line arranged on the substrate;
a data line crossing with the gate line, a gate insulating layer being interposed between the gate line and the data line;
a thin film transistor connected to the gate line and the data line at a crossing point of the gate line and the data line;
an organic passivation layer arranged on the thin film transistor;
a pixel electrode arranged on the substrate in a sub-pixel region and connected to the thin film transistor via a pixel contact hole penetrating the organic passivation layer; and
a repair portion arranged where the pixel electrode overlaps with a previous gate line.

25. The thin film transistor substrate of claim 24, wherein the repair portion comprises:
a gate extending portion extending from the previous gate line toward the sub-pixel region; and
a repair hole arranged in the repair portion and penetrating the organic passivation layer,
wherein the repair hole corresponds with the gate extending portion.

26. The thin film transistor substrate of claim 25, further comprising:
an inorganic passivation layer arranged below the organic passivation layer,
wherein the pixel contact hole penetrates the inorganic passivation layer, and the repair hole penetrates the inorganic passivation layer to expose the gate insulating layer.

27. The thin film transistor substrate of claim 25, wherein the thin film transistor further comprises:
a gate electrode arranged on the substrate and connected to the gate line;
a source electrode overlapping with the gate electrode and extending from the data line, a gate insulating layer being interposed between the source electrode and the gate electrode;
a drain electrode connected to the pixel electrode;
a semiconductor layer arranged on the gate insulating layer to form a channel between the source electrode and the drain electrode; and
an ohmic contact layer formed between the semiconductor layer and the source electrode, and between the semiconductor layer and the drain electrode.
